(19) United States
(12) Patent Application Publication
(10) Pub. No.: US 2007/0037067 A1
(43) Pub. Date: Feb. 15, 2007

(54) Optical pellicle with a filter and a vent

(76) Inventor: Ching-Bore Wang, Fremont, CA (US)

Correspondence Address: KOLISCH HARTWELL, P.C., 200 PACIFIC BUILDING, 520 SW YAMHILL STREET, PORTLAND, OR, 97204, US

(21) Appl. No.: 11/204,918

(22) Filed: Aug. 15, 2005

(51) Int. Cl. A47G 1/12; G03F 1/14; G03F 1/00

(52) U.S. Cl. 430/5; 428/14

(57) ABSTRACT

The present invention provides an optical pellicle frame that includes an exterior surface and an interior surface, at least one vent extending through the frame from the exterior surface to the interior surface, and a filter, wherein the filter is located within the vent and is at least three times closer to the interior surface of the frame than to the exterior surface of the frame.

### FIELD OF THE INVENTION

The invention relates to optical pellicles for photomasks used in photolithographic manufacturing. In particular, the invention relates to optical pellicles that may have pressure-equalization orifices formed within the pellicle frame.

### BACKGROUND OF THE INVENTION

The manufacture of semiconductor devices typically involves applying a layer of a photosensitive substance (a photoresist) to the surface of a target wafer. The photoresist is exposed to light in a selected pattern using a photomask, and the photoresist is then developed to leave exposed regions of the wafer. Typically, the exposed regions are subsequently etched away or otherwise modified, and the residual photoresist is removed. The pattern of the photomask typically possesses extremely fine details, and the presence of even tiny particles on the surface of the photomask can interfere with the accurate reproduction of the pattern on the target wafer.

To minimize particulate contamination at the mask surface, optical pellicles have been developed that protect the photomask. An optical pellicle is a frame-mounted transparent membrane that is attached to the photomask surface, so that contaminating particles fall onto the pellicle membrane and not the surface of the photomask. The pellicle frame holds the pellicle membrane at a sufficient distance above the mask surface so that any particles that may fall upon the membrane lie outside the focal plane of the illuminating light. As a result, these particles do not interfere with the projected mask pattern. The use of optical pellicles in semiconductor manufacture has helped mitigate the effects of contamination by dust and other particulates, and is widespread in the industry.

Pellicles may be packaged such that a protective cover is applied to the pellicle frame, opposite the side of the pellicle. This may create an airtight package with the pellicle, the pellicle frame, and the protective cover. Alternatively, a pellicle may be shipped already adjacent to the photomask, also forming an airtight package.

Pellicle packages are typically airtight to reduce contamination from dust and other contaminate particles. A problem occurs, however, when temperature and pressure change during shipping. This may cause the packaging and/or pellicle to expand and/or contract and pellicles may be damaged as a result. Therefore, pressure equalization orifices, or vents, have been designed in the frame, in the adhesive layer of a pellicle configuration, and even in the photomask itself. Some of these configurations have utilized filters to allow for pressure equalization without damaging the pellicle and without allowing contaminate particles to enter the area between the pellicle and photomask.

After a pellicle with a protective cover is received by a pellicle user the protective cover is typically removed and a photomask is mounted to the pellicle. Even before the pellicle membrane, protective cover or photomask are attached to the pellicle frame, however, the pellicle user may need to clean the pellicle frame in order to remove any contaminate particles that may be present on the frame. For pellicles utilizing one or more filters, the portion of the equalization orifice between the filter and the area to be bounded by the frame, the pellicle membrane, and photomask may be the most important portion to clean. This is because these surfaces are very close to where the photomask will be located, and any contaminate particles in this portion will have already passed through the filter section and will no longer be shielded from the photomask itself once the photomask is applied. Therefore, in order to facilitate this cleaning it may be ideal to use a pellicle employing an equalization orifice and a filter, where the filter is located very near to the area that will be bounded between the pellicle membrane, the pellicle frame, and the photomask.

Accordingly, it is an object of the present invention to develop a system for equalizing the pressure when a pellicle with a protective cover is shipped by air or is otherwise exposed to conditions that cause ambient pressure to increase or decrease. Specifically, it is an object of the present invention to develop a system that equalizes this pressure while allowing for easy cleaning of the pellicle frame before a pellicle membrane is mounted to the frame and before the pellicle is either mounted to a photomask or to a protective cover.

### SUMMARY OF THE INVENTION

The present invention provides an optical pellicle frame that includes an exterior surface and an interior surface, at least one vent extending through the frame, from the exterior surface to the interior surface, and a filter, wherein the filter is located within the vent and is at least three times closer to the interior surface of the frame than to the exterior surface of the frame.

Another aspect of the invention provides an optical pellicle that includes a pellicle frame and a pellicle membrane configured to cover the top surface of the frame. The pellicle frame includes an exterior surface, an interior surface, a top surface, and a bottom surface, at least one vent extending through the frame from the exterior surface to the interior surface, and at least one filter located within the vent, wherein the cross-sectional area of the pellicle frame at the location of the vent is configured in a U-shape,

so that no continuous surface exists from the top surface of the frame to the bottom surface for at least ¾ of the length of the frame spanning from the exterior surface of the frame to the interior surface.

Yet another aspect of the invention provides an optical pellicle that includes a pellicle frame, a pellicle membrane configured to cover the top surface of the frame, and a protective cover to which the bottom surface of the frame is mounted. The pellicle frame bounds an area between the frame, the pellicle membrane, and the protective cover, and the frame includes an exterior surface, a top surface and a bottom surface, at least one vent extending through the frame from the exterior surface to the bounded area, and at least one filter, wherein the distance from the exterior surface of the frame to the filter is at least three times the distance from the filter to the bounded area.

### BRIEF DESCRIPTION OF THE DRAWINGS

FIG. 1 is a side elevation sectional view of a prior art optical pellicle frame including a mounted pellicle membrane, wherein the frame has a vent extending through it and a filter positioned in the vent near the exterior surface of the frame.

FIG. 2 is a side elevation sectional view of an optical pellicle of a first embodiment of the present disclosure, including an optical pellicle frame, a pellicle membrane mounted to the top side of the frame, and a protective cover mounted to the frame's bottom side.

FIG. 3 is a side elevation sectional view of an optical pellicle frame of the first embodiment of the present disclosure, including a pellicle membrane mounted to the surface of the frame.

FIG. 4 is a side elevation sectional view of a second embodiment of an optical pellicle of the present disclosure.

FIG. 5 is a front elevation view of a third embodiment of an optical pellicle.

FIG. 6 is a side elevation sectional view of the optical pellicle from FIG. 5.

FIG. 7 is a front elevation view of a fourth embodiment of an optical pellicle.

FIG. 8 is a side elevation sectional view of the optical pellicle of FIG. 7.

FIG. 9 is a front elevation view of a fifth embodiment of an optical pellicle.

FIG. 10 is a side elevation sectional view of the optical pellicle of FIG. 9.

FIG. 11 is a front elevation view of a sixth embodiment of an optical pellicle.

FIG. 12 is a side elevation sectional view of the optical pellicle of FIG. 11.

FIG. 13 is a top plan view of the embodiments of FIGS. 2, 3, 5 and 7, showing the vent and filter in phantom.

FIG. 14 is a top plan view of the embodiments of FIGS. 9 and 11, showing the vent and filter in phantom.

### PRIOR ART ATTEMPTS TO SOLVE THE PROBLEM

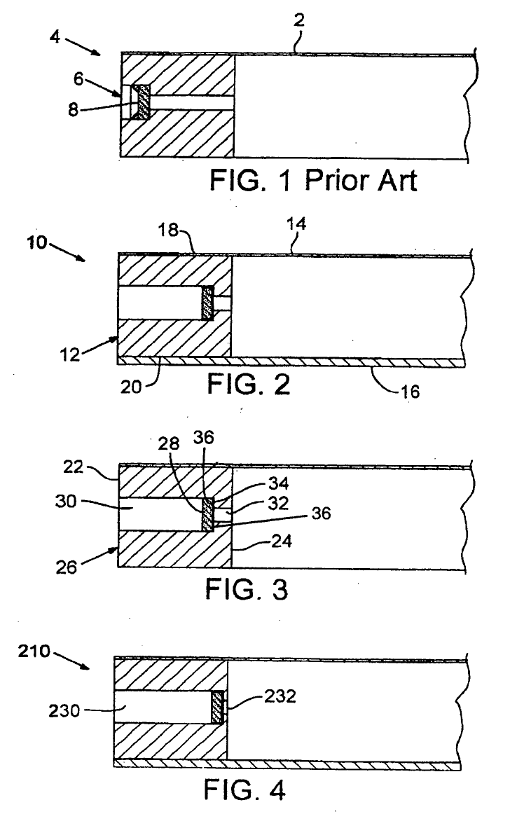

Before turning to the preferred embodiments, reference should first be made to FIG. 1, which depicts a prior art attempt to solve the problem of increased and decreased ambient pressure occurring during shipping of a pellicle-protected photomask. A pellicle membrane 2 is mounted to a pellicle frame 4. Frame 4 includes a substantially horizontally extending orifice channel 6. A filter 8 is mounted to the frame 4 in the orifice channel 6. Alternatively, some prior art (not shown) has attached the filter 8 to the outside over the frame 4, covering the orifice channel 6.

When optical pellicles are shipped to a customer, they typically are in the form of a pellicle membrane such as 2 mounted to a frame such as 4. Because they typically are not as yet mounted to a photomask, a protective plastic cover (not shown in FIG. 1), such as that depicted in my U.S. Pat. No. 5,820,950, is normally utilized. This protective cover is removable, and is generally mounted to the bottom side of the frame 4. The protective cover serves to prevent dust and other minute particulate from being deposited on the underside of pellicle membrane 2. This is important because any dust that adheres to the underside of the pellicle membrane would very possibly fall directly onto the photomask once the framed pellicle is mounted in place on the photomask. This dust might be reproduced in the surface of the silicon wafer during photolithography, thereby causing the wafer to be defective.

While the protective cover provides an effective seal to prevent particulate from depositing on the underside of the pellicle membrane, the airtight seal presents a problem when the cover-protected pellicle is transported by air to the customer's facility. Reduced ambient pressure will cause the pellicle membrane to bow outwardly as the atmospheric pressure captured in the space bounded by the pellicle membrane, frame and protective cover presses against the thin pellicle membrane. This may stretch or otherwise damage the pellicle membrane or adversely affect the bond between the membrane and the frame. Any such stretching or damage to the pellicle can be critical because it is important that a very high percentage of light pass directly through the pellicle membrane during photolithography, with very minimal reflection or refraction. Any distortion of the light could prevent accurate replication of the photomask pattern in the silicon wafer positioned therebelow during photolithography.

To prevent such damage to the pellicle membrane during shipping, a venting orifice channel such as that shown in FIG. 1 at 6 is sometimes provided in the pellicle frame 4. A filter 8 is typically provided to prevent dust and other particulate from entering the space under the pellicle membrane. Such a filter typically filters out dust and other particulate that is greater than 3 microns in size. Prior art similar to that of FIG. 1 is depicted in U.S. Pat. No. 4,833,051 to Imamura.

Other prior art attempts to solve this problem involve long channels (not shown in FIG. 1) being provided through the frame which might extend into the frame, along the center wall of the frame, and then into the interior space defined below the pellicle membrane. One such attempt is depicted in U.S. Pat. No. 6,103,427 to Storm. Another, somewhat similar attempt is shown in U.S. Pat. No. 5,529,819 to Campi, Jr. Alternatively, a channel (again, not shown in FIG. 1) might be formed through an adhesive layer between the frame 4 and a photomask which may be mounted to the bottom of the frame. It has been thought that a longer channel might serve the purpose of equalizing the pressure differential while reducing the likelihood of particulate making it all the way through such a long channel. This was thought to be particularly true when a long channel passes directly through the adhesive layer, because dust and other debris would be likely to adhere to the adhesive rather than being able to pass all the way through the long channel. Many of these prior art techniques have been described in a paper by Robert W. Murphy and Rick Boyd entitled “The Effect of Pressure Differentials on Pelliclized Photomasks.”

However, after manufacture of the frame and before the frame is mounted to a pellicle membrane, a protective cover or a photomask, the frame must be cleaned in order to make sure that when a photomask is mounted, contaminate particulate will not fall onto the photomask and harm the photolithographic process. For a frame utilizing a filter, the surfaces between the filter and the area that will be bounded by the frame, a pellicle membrane and a photomask are the surfaces where cleaning is of the utmost importance. Any contaminate particulate in this area may no longer have any impediments between its current location and the photomask, when mounted. A pellicle may thus be designed so as to allow for filtered pressure equalization while allowing for easy cleaning of the pellicle frame before its use with a photomask.

### DETAILED DESCRIPTION

As noted above, the use of optical pellicles in semiconductor manufacture has helped mitigate the effects of contamination by dust and other particulates, and use of such pellicles is widespread in the industry. FIG. 2 depicts an embodiment of an optical pellicle 10 of the present disclosure, including a pellicle frame 12, a pellicle membrane 14 and a protective cover 16. As shown, the pellicle membrane 14 typically mounts to the top surface 18 of the pellicle frame 12, while the protective cover 16 typically mounts to the frame's bottom surface 20. As shown in FIG. 3, the protective cover may be removed from the optical pellicle 10, leaving only the pellicle membrane 14 attached to the pellicle frame 12. This in turn allows a photomask (not shown) to be mounted to the bottom of the pellicle frame. As described above, it is well known that photomasks in this configuration are used in photolithography to permit replication of a pattern presented in the photomask into a silicon wafer while minimizing the effect of contaminate particulates.

Referring to FIG. 3, a pellicle frame 12 of the embodiment of FIG. 2 may include an exterior surface 22 and an interior surface 24. The frame will also normally include at least one vent 26 extending through the frame from the exterior surface 22 to the interior surface 24. A filter 28 will typically be placed inside the vent, preventing particles approximately 3 microns in size or greater from passing through the vent 26 from the exterior surface of the frame to the interior surface. As shown in FIG. 3, this filter will generally be located at least three times closer to the interior surface 24 of the frame than to the exterior surface 22.

Also as shown in FIG. 3, the cross-sectional area of the pellicle frame 12 at the location of the vent is typically configured in a substantial U-shape. As depicted, the cross-section of the frame looks like a ‘U’ that is sitting on its left side. The exterior surface 22 of the frame will normally represent the top of the arms of the ‘U,’ while the interior surface 24 of the frame will normally represent the bottom of the base of the ‘U.’ Finally, the filter 28 may appear to connect the parts of the frame that are separated by the vent so as to represent the top of the base of the ‘U.” A U-shaped cross-sectional area of a frame at the location of the vent will typically not have a continuous surface from the top surface 18 of the frame to the bottom surface 20 for at least ¾ of the length of the frame spanning from the exterior surface 22 of the frame to the interior surface 24.

The pellicle frame 12 is typically made of a plastic or aluminum, although other suitable materials may also be used. The pellicle frame, and the vent defined therein, may be formed in varying ways. Typically, this forming will be done by casting or molding. Furthermore, the vent 26 and other elements of the frame may be formed with machining techniques, such as drilling.

A finished optical pellicle 10 may often be shipped by air or by another method resulting in varying air pressures between the area bounded by an optical pellicle and its ambient surroundings, as previously discussed. The vent 26 will normally function to allow this area bounded by the pellicle frame 12, the pellicle membrane 14 and the protective cover 16 to remain at the same ambient pressure as the area surrounding the pellicle. Before, during, and after shipment, the filter 28 may function to keep contaminate particulate out of the bounded area.

However, as described above, before any structure is attached to the pellicle frame 12, the frame may need to be cleaned to rid the frame surfaces of any contaminate particulate that could impair the photolithographic process. Most importantly, the interior surface 24 of the pellicle frame 12 and the portion of the vent 26 that is located between the filter and the interior surface must be cleaned. The cleaning of this area is most important because any particulate that has reached these surfaces will often no longer be protected by the filter 28, which normally protects particulates from passing into this area. Contaminate particulates located in this area pose a great risk of falling onto the photomask and projecting onto the photoresist when the photomask is attached to the bottom of the pellicle frame 12. Any traditional method of cleaning a pellicle may be used, such as thoroughly wiping down the structures or blowing off any contaminate particulates from them. After cleaning and after the pellicle membrane and protective cover are mounted to the pellicle frame, the optical pellicle will typically be substantially clean and ready for the photolithographic process.

By locating the filter at least three times closer to the interior surface 24 of the pellicle frame than to the exterior surface 22, the most important area to be cleaned is therefore minimized, which may allow for easier and more effective cleaning. This, in turn, typically means that less particulate will fall onto the photomask, and it can therefore be expected that the number of defective silicon wafers formed during the photolithographic process will likewise decrease.

As is further depicted in FIG. 3, the at least one vent 26 of the pellicle frame may further include a first vent section 30 and a second vent section 32. The first vent section will often be defined by having a cross-sectional area that is greater than the second vent section, and the first vent section will often be located closer to the exterior surface 22 of the pellicle frame 12. Furthermore, the first vent section 30 is typically at least three times longer than the second vent section 32, and at least part of the vent 26 may extend through the pellicle frame 12 in a straight line. It is noted that the vent may be comprised of any number of sections, rather than just one or two.

The vent 26 of the pellicle frame 12 will also often include a filter seat 34 for positioning the filter 28 inside the vent 26, as shown in FIG. 3. An adhesive layer 36 will normally be placed between the filter and the filter seat for securing the filter inside the vent. The filter will often have a cross-sectional size that is greater than the cross-sectional size of the second vent section 32, but smaller than the cross-sectional size of the first vent section 30. In fact, the filter's cross-sectional size will be, in some embodiments, approximately the same size as that of the first vent section. Congruent with this filter size, the filter is generally positioned in the first vent section, abutting the second vent section. Again, this filter location coupled with the respective lengths of the first and second vent sections serve to minimize the area between the filter and the interior surface 24 of the pellicle frame.

Also consistent with the short length of the second vent section 32 relative to the first vent section 30, the filter 28 will typically have a height that is at least twice the length of the second vent section 32. As illustrated in the figures, the filter height is measured from the filter surface closest to the bottom surface 20 of the frame to the filter surface closest to the top surface 18 of the frame. In some embodiments this ratio of filter height to second vent section length will be at least four to one, rather than at least two to one. Furthermore, the length of the first vent section will typically be twice the height of the filter.

The filter 28 utilized by the optical pellicle 10 for allowing the passage of air but preventing the passage of certain contaminate particulates will often be a membrane-type filter. MF Millipore filters (trade name) or Cellotate filters (trade name) sold by Millipore Corporation may be used in the optical pellicle 10 of the present disclosure. These filters may be permeable filters and often are made of the raw materials cellulose-mixed ester or cellulose acetate.

FIG. 4 depicts a second embodiment of an optical pellicle 210. This optical pellicle typically has many of the same features as previously discussed, however the first vent section 230 in this embodiments may have a length that is at least six times the length of the second vent section 232. This setup may further minimize the surface area whose cleaning is most essential.

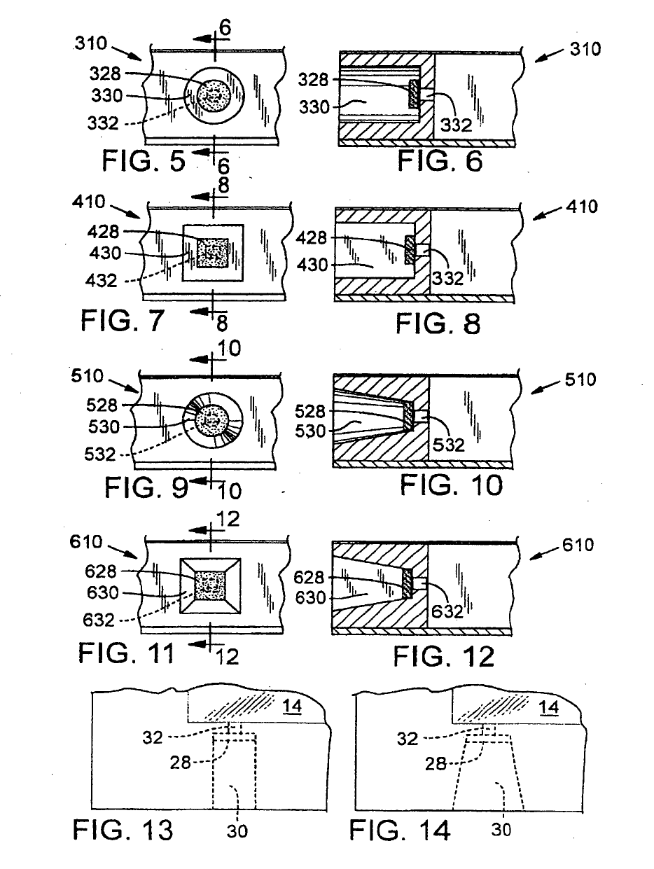

In most embodiments the cross-sectional shape of the vent 26 will be the same from the exterior surface 22 of the pellicle frame to the interior surface 24, although it may also have varying cross-sections. FIGS. 5 and 6 depict a third embodiment of an optical pellicle 310, wherein the first vent section 330 and the second vent section 332 both have circular cross sections. Furthermore, the first and second vent sections will typically resemble circular prisms, or cylinders.

FIGS. 7 and 8 show a fourth embodiment of an optical pellicle 410, which again contains many of the same features of the previous optical pellicles described above. This optical pellicle will often have a first vent section 430 and a second vent section 432 with rectangular cross sections, and the vent sections of this embodiment will therefore typically be in the shape of rectangular prisms. These cross sections will normally not only be rectangular, but also square.

A fifth embodiment of an optical pellicle 510 of the present disclosure is shown in FIGS. 9 and 10. While the cross section of the first vent section 530 is normally circular, this embodiment usually differs from others in that the prism formed by the first vent section is typically a conical prism. Furthermore, the second vent section 532 usually resemble a circular prism, or cylinder, although it may take the shape of any prism.

FIGS. 11 and 12 show a sixth embodiment of an optical pellicle 610, one in which both the first vent section 630 and second vent section 632 will typically have a square cross section. This embodiment is different, however, in that the first vent section will generally taper inwards as it progresses from the frame's exterior surface 622 to the frame's interior surface 624. It should finally be noted that the first vent section 30 and the second vent section 32 of any embodiment of the present disclosure may resemble any polygonal prism and corresponding cross section, and both vent sections may or may not have the same prism shape and/or cross section.

The disclosure set forth above may encompass multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements. It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower or equal in scope to the original claims, are also regarded as included within the subject matter of the inventions of the present disclosure.

What is claimed is:

1. An optical pellicle frame, comprising:
an exterior surface and an interior surface;
at least one vent extending through the frame, from the exterior surface to the interior surface, and
a filter, wherein the filter is located within the vent and is at least three times closer to the interior surface of the frame than to the exterior surface of the frame.

2. The optical pellicle frame of claim 1, wherein the at least one vent comprises a first vent section and a second vent section, the first vent section having a cross-sectional area that is greater than the cross-sectional area of the second vent section and being located closer to the exterior surface of the frame than the second vent section.

3. The optical pellicle frame of claim 2, wherein the first vent section is at least three times longer than the second vent section.

4. The optical pellicle frame of claim 2, wherein the first vent section is at least six times longer than the second vent section.

5. The optical pellicle frame of claim 2, wherein the height of the filter is at least twice the length of the second vent section.

6. The optical pellicle frame of claim 2, wherein the height of the filter is at least four times the length of the second vent section.

7. The optical pellicle frame of claim 2, wherein the length of the first vent section is at least two times the height of the filter.

8. The optical pellicle frame of claim 3, wherein at least part of the at least one vent extends entirely through the frame in a straight line, and the cross-sections of the first and second vent sections are substantially circular.

9. The optical pellicle frame of claim 3, wherein at least part of the at least one vent extends through the frame in a straight line, and the cross-sections of the first and second vent sections are substantially rectangular.

10. The optical pellicle frame of claim 3, wherein the cross-sectional area of the filter is smaller than the cross-sectional area of the first vent section, but larger than the cross-sectional area of the second vent section.

11. The optical pellicle frame of claim 3, wherein the cross-sectional area of the filter is approximately the same size as the cross-sectional area of the first vent section.

12. The optical pellicle frame of claim 3, wherein the first vent section further comprises a filter seat for positioning the filter.

13. The optical pellicle frame of claim 10, wherein the filter is at least partially located in the first vent section.

14. The optical pellicle frame of claim 12, further comprising an adhesive layer between the filter and the filter seat.

15. An optical pellicle, comprising:
a pellicle frame, including:
an exterior surface, an interior surface, a top surface, and a bottom surface;
at least one vent extending through the frame from the exterior surface to
the interior surface, and
at least one filter located within the vent, wherein the cross-sectional area
of the pellicle frame at the location of the vent is configured in a substantial U-shape,
so that no continuous surface exists from the top surface of the frame to the bottom surface for at least ¾ of the length of the frame spanning from the exterior surface of the frame to the interior surface, and
a pellicle membrane configured to cover the top surface of the frame.

16. An optical pellicle, comprising:
a pellicle frame bounding an area between the frame, a pellicle membrane, and a protective cover, the frame comprising:
an exterior surface, a top surface and a bottom surface;
at least one vent extending through the frame from the exterior surface to
the bounded area, and
at least one filter, wherein the distance from the exterior surface of the frame to the filter is at least three times the distance from the filter to the bounded area;
a pellicle membrane configured to cover the top surface of the frame, and
a protective cover to which the bottom surface of the frame is mounted.

17. The optical pellicle of claim 15, wherein the at least one vent comprises a first vent section and a second vent section, the first vent section having a cross-sectional area that is greater than the cross-sectional area of the second vent section and being located closer to the exterior surface of the frame than the second vent section.

18. The optical pellicle of claim 17, wherein the first vent section is at least three times longer than the second vent section.

19. The optical pellicle of claim 17, wherein the first vent section is at least six times longer than the second vent section.

20. The optical pellicle of claim 17, wherein the height of the filter is at least twice the length of the second vent section.

21. The optical pellicle of claim 17, wherein the height of the filter is at least four times the length of the second vent section.

22. The optical pellicle of claim 17, wherein the length of the first vent section is at least two times the height of the filter.

23. The optical pellicle of claim 18, wherein at least part of the at least one vent extends through the frame in a straight line, and the first and second vent sections have a substantially cylindrical shape.

24. The optical pellicle of claim 18, wherein at least part of the at least one vent extends through the frame in a straight line, and the first and second vent have substantially rectangular prism shapes.

25. The optical pellicle of claim 18, wherein at least part of the at least one vent extends through the frame in a straight line, and the first vent section has a substantially conical shape.

26. The optical pellicle of claim 18, wherein the cross-sectional area of the filter is smaller than the cross-sectional area of the first vent section, but larger than the cross-sectional area of the second vent section.

27. The optical pellicle of claim 18, wherein the cross-sectional area of the filter is approximately the same size as the cross-sectional area of the first vent section.

28. The optical pellicle of claim 18, wherein the first vent section further comprises a filter seat for positioning the filter.

29. The optical pellicle of claim 26, wherein the filter is at least partially located in the first vent section.

30. The optical pellicle of claim 28, further comprising an adhesive layer between the filter and the filter seat.
